(19) United States
(12) Patent Application Publication
(10) Pub. No.: US 2019/0041693 A1
(43) Pub. Date: Feb. 7, 2019

(54) DISPLAY PANEL

(71) Applicants: HKC Corporation Limited, Shenzhen City (CN); Chongqing HKC Optoelectronics Technology Co.,ltd., Chongqing (CN)

(72) Inventors: En-Tsung Cho, Chongqing (CN); Fengyun Yang, Chongqing (CN)

(21) Appl. No.: 16/141,231

(22) Filed: Sep. 25, 2018

Related U.S. Application Data
(63) Continuation of application No. PCT/CN2017/102458, filed on Sep. 20, 2017.

(30) Foreign Application Priority Data
Aug. 1, 2017 (CN) 201710644559.1

(51) Int. Cl. G02F 1/1335; G02F 1/1333; G02F 1/1343

(52) U.S. Cl. CPC G02F 1/133514; G02F 1/133345; G03F 7/004; G02F 1/134309; G02F 1/133512

(57) ABSTRACT

The present application discloses a display panel. The display panel includes a first substrate; a second substrate, parallel with and opposite to the first substrate; a plurality of first light shading parts, formed on the first substrate; a color filter layer, comprising a plurality of color filters, the color filters formed among the first light shading parts; a plurality of photosensitive elements, respectively formed on the first light shading parts; an organic insulating layer, formed on the color filter layer and between two adjacent photosensitive elements; and switch components, formed on the organic insulating layer.

### FIELD OF THE PRESENT APPLICATION

The present application relates to the technical field of displays, and particularly relates to a display panel.

### BACKGROUND

With the scientific and technological development and progress, liquid crystal displays have become mainstream products of the displays due to the advantages of thin device bodies, power saving, low radiation, etc., and are widely applied. Most liquid crystal displays on the market are backlight type liquid crystal displays, which comprise liquid crystal panels and backlight modules. A working principle of the liquid crystal panels is that liquid crystal molecules are placed between two parallel substrates, and a drive voltage is applied to the two substrates to control a rotary direction of the liquid crystal molecules, so as to refract light rays of the backlight modules to generate a picture.

Wherein, thin film transistor-liquid crystal displays (TFT-LCD) have the performances of low power consumption, excellent picture quality, higher production yield and the like, and thus have gradually played a leading role in the field of display at present. Similarly, the thin film transistor-liquid crystal display comprises a liquid crystal panel and a backlight module, the liquid crystal panel comprises a color filter substrate (CF Substrate, also called as color light filter substrate), a thin film transistor array substrate (TFT Substrate) and a mask, and transparent electrodes exist on opposite inner sides of the above substrates. A layer of liquid crystal (LC) molecules are clamped between the two substrates.

However, related display panels cannot adjust automatically according to an external environment, for example, cannot improve the brightness automatically when the light rays are strong.

It should be noted that the introduction on the background technology is merely intended to facilitate clear and complete explanation on the technical solutions of the present application, and to facilitate understanding by those skilled in the art. It cannot be considered that the above technical solutions are well known to those skilled in the art just because these solutions are elaborated in the background technology of the present application.

### SUMMARY

In view of the above defects, the present application aims to solve the technical problem about providing a display panel which can adjust automatically according to an external environment.

The present application provides a display panel. The display panel includes a first substrate; a second substrate, disposed parallel with and opposite to the first substrate; a plurality of first light shading parts, formed on the first substrate; a color filter layer, including a plurality of color filters, the color filters being formed among the first light shading parts; a plurality of photosensitive elements, formed on the first light shading parts correspondingly; an organic insulating layer, formed on the color filter layer and between two adjacent photosensitive elements; and switch components, formed on the organic insulating layer. Wherein an upper surface of the organic insulating layer and upper electrodes of the photosensitive elements are positioned on the same surface, and the switch component is formed above the organic insulating layer. Wherein photosensitive conductive layers are formed above the photosensitive elements. Wherein the first light shading parts are made of a conductive material; Wherein the photosensitive elements include first N-type doped layers, iodine doped layers and P-type doped layers from the first light shading parts; Wherein the switch component includes a gate electrode metal layer, a gate electrode insulating layer, an active layer, a second N-type doped layer, and a source electrode metal layer and a drain electrode metal layer sequentially from the organic insulating layer; the switch components include a passivation layer disposed on an outer surface of the switch components, and a conductive layer is formed on a part of an outer side of the passivation layer close to the photosensitive elements. Wherein the photosensitive conductive layers are extending parts of the conductive layer.

The present application also provides a display panel. The display panel includes a first substrate; and a second substrate, parallel with and opposite to the first substrate; a plurality of first light shading parts, formed on the first substrate; a color filter layer, including a plurality of color filters, the color filters being formed among the first light shading parts; a plurality of photosensitive elements, formed on the first light shading parts, correspondingly; an organic insulating layer, formed on the color filter layer and between two adjacent photosensitive elements; and switch components, formed on the organic insulating layer.

In an embodiment, an upper surface of the organic insulating layer and upper electrodes of the photosensitive elements are positioned on the same surface, and the switch components are formed above the organic insulating layer.

In an embodiment, second light shading parts are further formed on the first substrate, and the second light shading parts are disposed between every two adjacent first light shading parts.

In an embodiment, a plurality of second light shading parts are formed between two adjacent color filters correspondingly.

In an embodiment, photosensitive conductive layers are formed above the photosensitive elements.

In an embodiment, the first light shading parts are made of a conductive material.

In an embodiment, the photosensitive elements include first N-type doped layers, iodine doped layers and P-type doped layers from the first light shading parts.

In an embodiment, the switch component includes: a gate electrode metal layer, a gate electrode insulating layer, an active layer and a second N-type doped layer, and a source electrode metal layer and a drain electrode metal layer sequentially from the organic insulating layer; and the switch component includes a passivation layer disposed on an outer surface of the switch component, and a conductive layer is formed on the part of the outer side of the passivation layer close to the photosensitive elements.

In an embodiment, the photosensitive conductive layers are extending parts of the conductive layer.

In an embodiment, second light shading parts are further formed on the first substrate, and the second light shading parts are disposed between two adjacent first light shading parts.

In an embodiment, the second light shading parts are formed between every two adjacent color filters.

In an embodiment, photosensitive conductive layers are formed above the photosensitive elements.

In an embodiment, the first light shading parts are made of a conductive material.

In an embodiment, the first light shading parts are made of a conductive material.

In an embodiment, the first light shading parts are made of a conductive material.

In an embodiment, the photosensitive elements include first N-type doped layers, iodine doped layers and P-type doped layers from the first light shading parts.

In an embodiment, the switch component includes: a gate electrode metal layer, a gate electrode insulating layer, an active layer and a second N-type doped layer, and a source electrode metal layer and a drain electrode metal layer sequentially from the organic insulating layer; and the switch component includes a passivation layer disposed on the outer surface of the switch component, and a conductive layer is formed on the part of the outer side of the passivation layer close to the photosensitive elements.

In an embodiment, the photosensitive conductive layers are extending parts of the conductive layer.

The present application also provides a display panel. The display panel includes a first substrate; a second substrate, disposed parallel with and opposite to the first substrate; a plurality of first light shading parts, formed on the first substrate, being made of a conductive material; a color filter layer, including a plurality of color filters, the color filters being formed among the first light shading parts; a plurality of photosensitive elements, formed on the first light shading parts correspondingly, and including first N-type doped layers, iodine doped layers and P-type doped layers from the first light shading parts; an organic insulating layer, formed on the color filter layer and between two adjacent photosensitive elements; and switch components, formed on the organic insulating layer, wherein the switch component includes: a gate electrode metal layer, a gate electrode insulating layer, an active layer and a second N-type doped layer, and a source electrode metal layer and a drain electrode metal layer sequentially from the organic insulating layer; the switch component also includes a passivation layer disposed on an outer surface of the switch component, and a conductive layer is formed on the part of the outer side of the passivation layer close to the photosensitive elements; and parts the conductive layer of are extended on the photosensitive elements. Wherein an upper surface of the organic insulating layer and upper electrodes of the photosensitive elements are positioned on the same surface, and the switch components are formed above the organic insulating layer. Wherein second light shading parts are further formed on the first substrate, and the second light shading parts are disposed between two adjacent first light shading parts.

The present application may adopt a TFT-ARRAY ON CF (AOC) technology, i.e., a technology of forming an array substrate on a color filter substrate, meanwhile, the photosensitive elements are made in a first functional area, in this way, the display panel can sense a change condition of the environment where the display panel is by the photosensitive elements, and particularly, can sense the change condition of the intensity of external light rays, in this way, when the light rays are strong, the display panel can automatically adjust to improve the brightness to avoid a condition that a display picture which is too dark cannot be viewed clearly; when the light rays are weak, the brightness can be correspondingly decreased to avoid the damage to eyes caused by a too bright picture; in addition, the photosensitive elements are formed above the first light shading parts in a one-to-one manner or in a proportional manner; due to such arrangement, the photosensitive elements can obtain the condition of the external environment of a display area of the display panel, particularly, the condition of the external light rays in the display area, therefore, a basis is provided for automatic adjustment of the display panel; while the first light shading parts play a light shading role, and prevent the light rays in a backlight source of the display panel from irradiating the photosensitive elements, and a sensing precision is improved; in addition, the organic insulating layer exists as a contact part between an array substrate layer and a color filter substrate layer. The photosensitive elements are proportionally disposed between the adjacent organic insulating layers, and of course may also be disposed between every group of adjacent organic insulating layers.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic view of a display panel according to an embodiment of the present application;

FIG. 2 is a flowchart of a manufacturing method for a display panel according to an embodiment of the present application; and

FIG. 3 is a schematic diagram of a display device according to an embodiment of the present application.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the description of the disclosure, terms such as “center”, “transverse”, “above”, “below”, “left”, “right”, “vertical”, “horizontal”, “top”, “bottom”, “inside”, “outside”, etc. for indicating orientations or positional relationships refer to orientations or positional relationships as shown in the drawings; the terms are for the purpose of illustrating the disclosure and simplifying the description rather than indicating or implying the device or element must have a certain orientation and be structured or operated by the certain orientation, and therefore cannot be regarded as limitation with respect to the disclosure. Moreover, terms such as “first” and “second” are merely for the purpose of illustration and cannot be understood as indicating or implying the relative importance or implicitly indicating the number of the technical feature. Therefore, features defined by “first” and “second” can explicitly or implicitly include one or more the features. In the description of the disclosure, unless otherwise indicated, the meaning of “plural” is two or more than two. In addition, the term “comprise” and any variations thereof are meant to cover a non-exclusive inclusion.

In the description of the disclosure, is should be noted that, unless otherwise clearly stated and limited, terms “mounted”, “connected with” and “connected to” should be understood broadly, for instance, can be a fixed connection, a detachable connection or an integral connection; can be a mechanical connection, can also be an electrical connection; can be a direct connection, can also be an indirect connection by an intermediary, can be an internal communication of two elements. A person skilled in the art can understand concrete meanings of the terms in the disclosure as per specific circumstances.

The terms used herein are only for illustrating concrete embodiments rather than limiting the exemplary embodiments. Unless otherwise indicated in the content, singular forms “a” and “an” also include plural. Moreover, the terms “comprise” and/or “include” define the existence of described features, integers, steps, operations, units and/or components, but do not exclude the existence or addition of one or more other features, integers, steps, operations, units, components and/or combinations thereof.

The disclosure will be further described in detail with reference to accompanying drawings and preferred embodiments as follows.

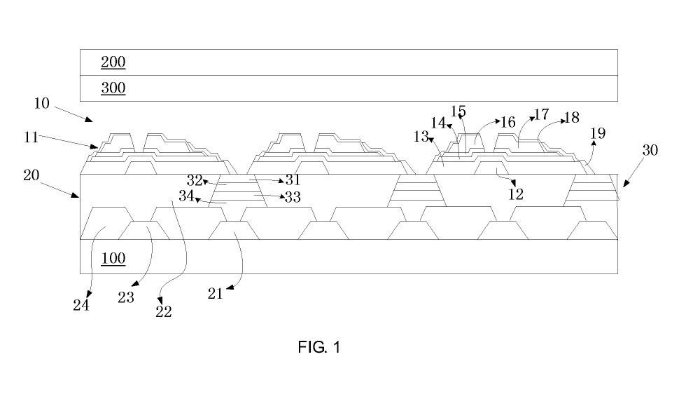

FIG. 1 is a schematic view of a display panel according to an embodiment of the present application, referring to FIG. 1, the display panel includes:

a first substrate 100; and

a second substrate 200, parallel with and opposite to the first substrate 100;

a plurality of first light shading parts 21, formed on the first substrate 100;

a color filter layer 24, including a plurality of color filters, the color filters being formed among the first light shading parts 21;

a plurality of photosensitive elements 30, respectively formed on the first light shading parts 21;

an organic insulating layer 22, formed on the color filter layer 24 and between every two adjacent photosensitive elements 30; and

switch components 11, formed on the organic insulating layer 22.

The present application may adopt a TFT-ARRAY ON CF (AOC) technology, i.e., a technology of forming an array substrate on a color filter substrate, meanwhile, the photosensitive elements are made in a first functional area 10. In this way, the display panel can sense a change condition of the environment where the display panel is by the photosensitive elements, and particularly, can sense the change condition of the intensity of external light rays. As such, when the light rays are strong, the display panel can automatically adjust to improve the brightness to avoid a condition that a display picture which is too dark cannot be viewed clearly; when the light rays are weak, the brightness can be correspondingly decreased to avoid the damage to eyes caused by a too bright picture. In addition, the photosensitive elements are formed above the first light shading parts in a one-to-one manner or in a proportional manner. Due to such arrangement, the photosensitive elements can obtain the condition of the external environment of a display area of the display panel, particularly, the condition of the external light rays in the display area, therefore, a basis is provided for automatic adjustment of the display panel. The first light shading parts can play a light shading role, and prevent the light rays in a backlight source of the display panel from irradiating the photosensitive elements, and a sensing precision is improved. In addition, the organic insulating layer exists as a contact part between an array substrate layer and a color filter substrate layer. The photosensitive elements are proportionally disposed between the adjacent organic insulating layers, and of course may also be disposed between every group of adjacent organic insulating layers.

Unless specially stated, in the following embodiments, the bottom plane of the switch component is used as an interface. The part below the bottom plane of the switch component is set as a first functional area 10; and respective layers above are defined as a second functional area 20. In other words, the first functional area 10 is formed on the first substrate 100; the second functional area 20 is formed on the first functional area 10; the switch components 11 are disposed in the second functional area 20; and the photosensitive elements 30 and the color filter layer 24 are disposed in the first functional area 10.

Wherein the display panel is formed by closing the first substrate 100 and the second substrate 200, the surface of the second substrate 200 adjacent to the first substrate 100 is provided with a common electrode 300. The common electrode 300 may be made of an indium tin oxide (ITO) material.

In the present embodiment, an upper surface of the organic insulating layer 22 and upper electrodes of the photosensitive elements 30 are positioned on the same surface, and the switch components 11 are formed above the organic insulating layer 22. In the present embodiment, the common upper surface of the inorganic insulating layer and the photosensitive elements is disposed to be flat, so that the switch components can be formed thereon; while the photosensitive elements are correspondingly disposed below the middles of two adjacent switch components.

In the present embodiment, the second light shading parts 23 can be further formed on the first substrate 100, and the second light shading parts 23 are disposed between two adjacent first light shading parts 21. The second light shading parts are disposed between two adjacent first light shading parts and below the corresponding switch components.

In the present embodiment, the second light shading parts 23 are disposed between two adjacent color filters. In the present embodiment, the first substrate has the first light shading parts and the second light shading parts thereon. The first light shading parts and the second light shading parts are disposed on the same layer and may be made of the same material or different materials. The first light shading parts are disposed on the lower parts in all color filters, and the second light shading parts are disposed between two adjacent color filters. In this way, the photosensitive elements are disposed above the first light shading parts, below the contact part of two adjacent switch components and between two adjacent color filter layers, and are between two adjacent organic insulating layers.

In the present embodiment, optionally, the photosensitive conductive layers 31 can be disposed above the photosensitive elements 30.

The first light shading parts 21 are made of a conductive material. In the present embodiment, the photosensitive conductive layers and the first light shading parts exist as upper electrodes and lower electrodes. For the photosensitive elements, under the irradiation of external light rays, a corresponding electric signal will be generated between the upper electrodes and the lower electrodes according to an irradiation intensity, the display panel acquires the environment condition of an external light ray environment where the display panel is according to the electric signal, so as to perform automatic adjustment. In addition, the first light shading parts may be made of a conductive material, so as to serve as lower electrodes of the photosensitive elements, and two purposes are realized by one operation. Besides, such a design is favorable for improving an aperture rate of the display panel of the present application.

In the present embodiment, optionally, the photosensitive elements 30 include: first N-type doped layers 34, iodine doped layers 33 and P-type doped layers 32 sequentially from the first light shading parts 21. In the present embodiment, the photosensitive elements sequentially include the first N-type doped layers, the iodine doped layers and the P-type doped layers from top to bottom, which form the photosensitive elements together with the upper and lower electrodes. Therefore, the condition of a light ray intensity of the external environment where the display panel is can be obtained, and the display panel is helped for automatic adjustment.

Wherein the P-type doped layers 32 may optionally adopt high-concentration doped P-type amorphous silicon (P+α-Si). The iodine doped layers 33 may adopt iodine doped amorphous silicon. The first N-type doped layers 34 may adopt high-concentration doped N-type amorphous silicon.

In the present embodiment, optionally, the switch component 11 can include: a gate electrode metal layer 12, a gate electrode insulating layer 13, an active layer 14 and a second N-type doped layer 15 sequentially from the organic insulating layer, as well as a source electrode metal layer 16 and a drain electrode metal layer 17;

The switch component 11 includes a passivation layer 18 disposed on the outer surface of the switch component 11, and a conductive layer 19 is formed on the part of the outer side of the passivation layer 18 close to the photosensitive elements 30. In the present embodiment, the passivation layer wraps the outer part of the switch component, while the passivation layer partially covers the conductive layer, and is an indium tin oxide (i.e., ITO) layer in fact, the conductive layer downwards extends in an interval between the switch components, and an extending part thereof serves as an upper electrode of the photosensitive element. The active layer 14 optionally may adopt amorphous silicon (α-Si), and the second N-type doped layer 15 may adopt the high concentration doped N-type amorphous silicon like the first N-type doped layer 34.

In the present embodiment, optionally, the photosensitive conductive layers 31 are extending parts of the conductive layer 19. In the present embodiment, the conductive layer downwards extends in the interval between the switch components, and an extending part of the conductive layer can exist as the upper electrode of the photosensitive element.

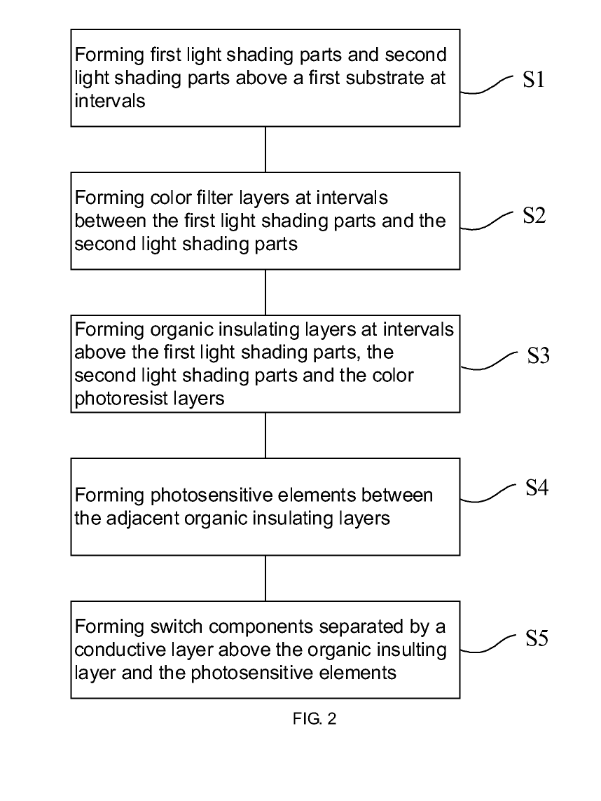

FIG. 2 is a flowchart of a manufacturing method for a display panel according to an embodiment of the present application, and referring to FIG. 2, the manufacturing method for a display panel is disclosed and includes the steps:

S1: forming first light shading parts and second light shading parts above a first substrate at intervals;

S2: forming color filter layers at intervals between the first light shading parts and the second light shading parts;

S3: forming organic insulating layers at intervals above the first light shading parts, the second light shading parts and the color filter layers;

S4: forming photosensitive elements between the adjacent organic insulating layers; and

S5: forming switch components separated by a conductive layer above the organic insulting layer and the photosensitive elements. In addition, a common electrode and a second substrate are further disposed above the switch components.

The manufacturing method of present application may adopt a TFT-ARRAY ON CF (AOC) technology, i.e., a technology of forming an array substrate on a color filter substrate, in the display panel, the photosensitive elements are made in a first functional area, in this way, the display panel can sense a change condition of the environment where the display panel is by the photosensitive elements, and particularly, can sense the change condition of the intensity of external light rays, in this way, when the light rays are strong, the display panel can automatically adjust to improve the brightness to avoid a condition that a display picture which is too dark cannot be viewed clearly; and when the light rays are weak, the brightness can be correspondingly decreased to avoid the damage to eyes caused by a too bright picture.

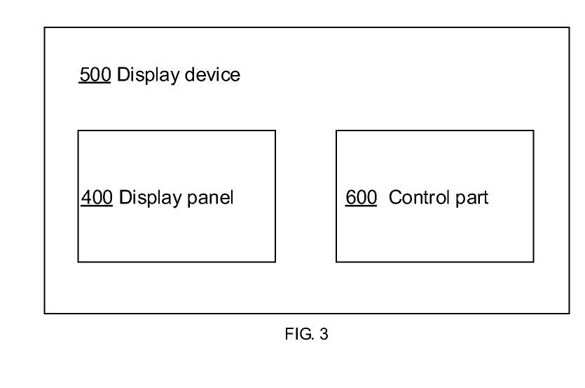

FIG. 3 is a schematic diagram of a display device according to an embodiment of the present application, and referring to FIG. 3, the present application further discloses a display device 500, including: a control part 600, and the display panel 400 according to any embodiment of the present application.

The present application may adopt a TFT-ARRAY ON CF (AOC) technology, i.e., a technology of forming an array substrate on a color filter substrate, meanwhile, the photosensitive elements are made in a first functional area, in this way, the display panel can sense a change condition of the environment where the display panel is by the photosensitive elements, and particularly, can sense the change condition of the intensity of external light rays, in this way, when the light rays are strong, the display panel can automatically adjust to improve the brightness to avoid a condition that a display picture which is too dark cannot be viewed clearly; and when the light rays are weak, the brightness can be correspondingly decreased to avoid the damage to eyes caused by a too bright picture.

The solutions of the present application may be applied to liquid crystal display (LCD) panels, and may also be applied to organic light-emitting diode (OLED) panels, and other types of panels applicable for such a technology.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A display panel, comprising
a first substrate;
a second substrate, disposed parallel with and opposite to the first substrate;
a plurality of first light shading parts, formed on the first substrate;
a color filter layer, comprising a plurality of color filters, the color filters being formed among the first light shading parts;
a plurality of photosensitive elements, formed on the first light shading parts correspondingly;
an organic insulating layer, formed on the color filter layer and between two adjacent photosensitive elements; and
switch components, formed on the organic insulating layer;
wherein an upper surface of the organic insulating layer and upper electrodes of the photosensitive elements are positioned on the same surface, and the switch component is formed above the organic insulating layer;
wherein photosensitive conductive layers are formed above the photosensitive elements;
wherein the first light shading parts are made of a conductive material;
wherein the photosensitive elements comprise first N-type doped layers, iodine doped layers and P-type doped layers from the first light shading parts;
wherein the switch component comprises:
a gate electrode metal layer, a gate electrode insulating layer, an active layer, a second N-type doped layer, and a source electrode metal layer and a drain electrode metal layer sequentially from the organic insulating layer; the switch components comprise a passivation layer disposed on an outer surface of the switch components, and a conductive layer is formed on a part of an outer side of the passivation layer close to the photosensitive elements;
wherein the photosensitive conductive layers are extending parts of the conductive layer.

2. A display panel, comprising
a first substrate; and
a second substrate, parallel with and opposite to the first substrate;
a plurality of first light shading parts, formed on the first substrate;
a color filter layer, comprising a plurality of color filters, the color filters being formed among the first light shading parts;
a plurality of photosensitive elements, formed on the first light shading parts, correspondingly;
an organic insulating layer, formed on the color filter layer and between two adjacent photosensitive elements; and
switch components, formed on the organic insulating layer.

3. The display panel according to claim 2, wherein an upper surface of the organic insulating layer and upper electrodes of the photosensitive elements are positioned on the same surface, and the switch components are formed above the organic insulating layer.

4. The display panel according to claim 2, wherein second light shading parts are further formed on the first substrate, and the second light shading parts are disposed between every two adjacent first light shading parts.

5. The display panel according to claim 4, wherein a plurality of second light shading parts are formed between two adjacent color filters correspondingly.

6. The display panel according to claim 2, wherein photosensitive conductive layers are formed above the photosensitive elements.

7. The display panel according to claim 2, wherein the first light shading parts are made of a conductive material.

8. The display panel according to claim 7, wherein the photosensitive elements comprise:
first N-type doped layers, iodine doped layers and P-type doped layers from the first light shading parts.

9. The display panel according to claim 6, wherein the switch component comprises: a gate electrode metal layer, a gate electrode insulating layer, an active layer and a second N-type doped layer, and a source electrode metal layer and a drain electrode metal layer sequentially from the organic insulating layer; and
the switch component comprises a passivation layer disposed on an outer surface of the switch component, and a conductive layer is formed on the part of the outer side of the passivation layer close to the photosensitive elements.

10. The display panel according to claim 9, wherein the photosensitive conductive layers are extending parts of the conductive layer.

11. The display panel according to claim 3, wherein second light shading parts are further formed on the first substrate, and the second light shading parts are disposed between two adjacent first light shading parts.

12. The display panel according to claim 11, wherein the second light shading parts are formed between every two adjacent color filters.

13. The display panel according to claim 11, wherein photosensitive conductive layers are formed above the photosensitive elements.

14. The display panel according to claim 11, wherein the first light shading parts are made of a conductive material.

15. The display panel according to claim 13, wherein the first light shading parts are made of a conductive material.

16. The display panel according to claim 6, wherein the first light shading parts are made of a conductive material.

17. The display panel according to claim 16, wherein the photosensitive elements comprise:
first N-type doped layers, iodine doped layers and P-type doped layers from the first light shading parts.

18. The display panel according to claim 17, wherein the switch component comprises: a gate electrode metal layer, a gate electrode insulating layer, an active layer and a second N-type doped layer, and a source electrode metal layer and a drain electrode metal layer sequentially from the organic insulating layer; and
the switch component comprises a passivation layer disposed on the outer surface of the switch component, and a conductive layer is formed on the part of the outer side of the passivation layer close to the photosensitive elements.

19. The display panel according to claim 18, wherein the photosensitive conductive layers are extending parts of the conductive layer.

20. A display panel, comprising
a first substrate;
a second substrate, disposed parallel with and opposite to the first substrate;
a plurality of first light shading parts, formed on the first substrate, being made of a conductive material;
a color filter layer, comprising a plurality of color filters, the color filters being formed among the first light shading parts;
a plurality of photosensitive elements, formed on the first light shading parts correspondingly, and comprising first N-type doped layers, iodine doped layers and P-type doped layers from the first light shading parts;
an organic insulating layer, formed on the color filter layer and between two adjacent photosensitive elements; and
switch components, formed on the organic insulating layer, wherein the switch component comprises: a gate electrode metal layer, a gate electrode insulating layer, an active layer and a second N-type doped layer, and a source electrode metal layer and a drain electrode metal layer sequentially from the organic insulating layer; the switch component also comprises a passivation layer disposed on an outer surface of the switch component, and a conductive layer is formed on the part of the outer side of the passivation layer close to the photosensitive elements; and parts the conductive layer of are extended on the photosensitive elements;
wherein an upper surface of the organic insulating layer and upper electrodes of the photosensitive elements are positioned on the same surface, and the switch components are formed above the organic insulating layer;
wherein second light shading parts are further formed on the first substrate, and the second light shading parts are disposed between two adjacent first light shading parts.
